(19) United States
(12) Patent Application Publication
(10) Pub. No.: US 2026/0302730 A1
(43) Pub. Date: Oct. 1, 2026

(54) MULTI-CAVITY CASCADED COUPLED VERTICAL-CAVITY SURFACE-EMITTING LASER AND MANUFACTURE METHOD THEREOF

(71) Applicant: UNIVERSITY OF ELECTRONIC SCIENCE AND TECHNOLOGY OF CHINA, Chengdu (CN)

(72) Inventors: Jiang WU, Chengdu (CN); Zhiting TANG, Chengdu (CN); Chuanlin LI, Chengdu (CN); Aobo REN, Chengdu (CN)

(73) Assignee: UNIVERSITY OF ELECTRONIC SCIENCE AND TECHNOLOGY OF CHINA, Chengdu (CN)

(21) Appl. No.: 19/370,783

(22) Filed: Oct. 28, 2025

(30) Foreign Application Priority Data
Mar. 26, 2025 (CN) 202510369062.8

(51) Int. Cl. H01S 5/183; H01S 5/10; H01S 5/343

(52) U.S. Cl. CPC H01S 5/18361; H01S 5/1021; H01S 5/34313; H01S 5/34353

(57) ABSTRACT

A multi-cavity cascaded coupled vertical-cavity surface-emitting laser includes, from top to bottom, a top reflector, an oxidation layer, an active region, a predetermined number of assemblies of intermediate reflector and passive cavity, a bottom reflector, and a substrate. A first electrode is arranged on a side of the top reflector away from the oxidation layer, and a second electrode is arranged at two ends of a side of an assembly of intermediate reflector and passive cavity closest to the top reflector. Each assembly includes an intermediate reflector and a passive cavity located on a side of the intermediate reflector away from the active region.

### CROSS-REFERENCE TO RELATED APPLICATIONS

This application claims priority to Chinese patent application NO. 202510369062.8, titled “MULTI-CAVITY CASCADED COUPLED VERTICAL-CAVITY SURFACE-EMITTING LASER AND MANUFACTURE METHOD THEREOF”, filed Mar. 26, 2025, with the China National Intellectual Property Administration, which is incorporated herein by reference in its entirety.

### FIELD

The present disclosure relates to the field of vertical-cavity surface-emitting laser manufacture, and in particular to a multi-cavity cascaded coupled vertical-cavity surface-emitting laser and a manufacture method thereof.

### BACKGROUND

The vertical-cavity surface-emitting laser (VCSEL) has rapidly occupied the semiconductor laser market in recent years, playing a crucial role in various fields such as optical communications, sensing, and storage. The atomic clock, as an advanced timekeeping apparatus with precision reaching 1 second error per 20 million years, is widely applied to global navigation systems. An atomic clock sensor relies on spectral analysis of an alkali atom (such as rubidium or cesium), and the alkali atom is contained within a miniature vapor cavity. The corresponding spectral wavelengths of cesium are 894.6 nm (D1) and 852.3 nm (D2), and the corresponding spectral wavelengths of rubidium are 795.0 nm (D1) and 780.2 nm (D2). Due to low power consumption and a circular output beam profile, the VCSEL has become a preferred light source for the atomic clock.

The chip-scale atomic clock (CSAC), due to its compact structure and high efficiency, has become an ideal choice for satellite communications and global navigation satellite systems (GNSS). The core mechanism of the CSAC is based on a coherent population trapping (CPT) effect, whose performance critically depends on a spectral linewidth of a light source. The VCSEL, due to its small size, light weight, and low power consumption, can meet the size, weight, and power (SWaP) requirements of the CSAC. In practice, the conventional VCSEL typically exhibits a linewidth around 100 MHz, which significantly exceeds a 1-10 MHz range required for an advanced atomic system. The range matches a natural transition linewidth (5 MHz) of the cesium atom achievable through atomic beam, atom trapping, or ion trapping techniques.

In related art, the methods for achieving a narrow-linewidth semiconductor laser all present some disadvantages. For example, a linewidth enhancement factor reduction method requires careful consideration of complex factors including a charge carrier concentration and a differential gain in an active region; and the conventional optical feedback technology depends on complex secondary epitaxial growth and precise manufacture control, increasing the difficulty and cost of the process. Extending an effective cavity length provides a relatively simple method for linewidth narrowing, but a high electric field intensity in the active region of the conventional extended-cavity of the VCSEL leads to substantial oxidation confinement factors, increasing the difficulty of achieving single-mode operation.

### SUMMARY

One embodiment of the present disclosure is to address the issue of a short effective cavity length and a large spectral linewidth in conventional vertical-cavity surface-emitting lasers. A novel multi-cavity cascaded coupled vertical-cavity surface-emitting laser based on inter-cavity electric field modulation is provided according to the present disclosure. An optical field is effectively coupled from an active cavity into multiple cascaded passive cavities, and a photon undergoes multiple cycles within the passive cavities before being emitted, thereby extending a photon lifetime to reduce a linewidth, and showing significant advantages.

To achieve the above objective, the following embodiments are provided according to the present disclosure.

In one embodiment, a multi-cavity cascaded coupled vertical-cavity surface-emitting laser is provided according to the present disclosure. The laser includes, from top to bottom, a top reflector, an oxidation layer, an active region, a predetermined number of assemblies of intermediate reflector and passive cavity, a bottom reflector, and a substrate. A first electrode is arranged on a side of the top reflector away from the oxidation layer, and a second electrode is arranged at two ends of a side of an assembly of intermediate reflector and passive cavity closest to the top reflector.

Further, each of the assemblies of intermediate reflector and passive cavity includes an intermediate reflector and a passive cavity located on a side of the intermediate reflector away from the active region.

Further, the predetermined number of intermediate reflector and passive cavity assemblies is 2 to 6.

Further, the top reflector includes 21 to 25 pairs of p-type doped Al_{0.92}Ga_{0.08}As/Al_{0.16}Ga_{0.84}As, with a doping concentration of 2×10¹⁸ to 3×10¹⁸ cm⁻³.

Further, the active region includes three repeating units. Each of the three repeating units includes a 6 nm In_{0.135}Ga_{0.865}As quantum well and an 8 nm Al_{0.25}Ga_{0.75}As barrier.

Further, each intermediate reflector includes, from bottom to top, a first n-type doped layer, a second n-type doped layer, and a third n-type doped layer.

The first n-type doped layer includes 11 to 12.5 pairs of Al_{0.92}Ga_{0.08}As/Al_{0.16}Ga_{0.84}As, with a doping concentration of 1×10¹⁸ to 1.5×10¹⁸ cm⁻³. The second n-type doped layer includes an Al_{0.16}Ga_{0.84}As layer with a predetermined optical thickness, with a doping concentration of 2×10¹⁸ cm⁻³. The third n-type doped layer includes 7 to 9.5 pairs of Al_{0.92}Ga_{0.08}As/Al_{0.16}Ga_{0.84}As, with a doping concentration of 1.5×10¹⁸ to 2×10¹⁸ cm⁻³.

Further, the predetermined optical thickness is λ to λ2.

Further, a dip exists in a reflection spectrum of the intermediate reflector.

Further, the top reflector has a reflectivity of 99.3% to 99.7%, the intermediate reflector has a reflectivity of 15% to 45%, and the bottom reflector has a reflectivity of 99.9%.

In one embodiment, a method for manufacturing the above multi-cavity cascaded coupled vertical-cavity surface-emitting laser is further provided according to the present disclosure, including:
S1, providing a substrate, and sequentially providing, on the substrate, a bottom reflector, a predetermined number of assemblies of intermediate reflector and passive cavity, an active region, an oxidation layer, and a top reflector, to obtain a first preform; and
S2, arranging a first electrode on the top reflector of the first preform, and arranging a second electrode on a side of a first assembly of intermediate reflector and passive cavity closest to the top reflector of the first preform, to complete manufacture of the laser.

The present disclosure has the following advantages over the related art.

The multi-cavity cascaded coupled vertical-cavity surface-emitting laser according to the present disclosure addresses the issue that the requirements on a light source for a precision timing atomic clock cannot be satisfied due to a limited effective cavity length and a relatively large lasing spectral linewidth. Without an external cavity, the multi-cavity cascaded coupling linewidth compression method achieves a laser spectral linewidth below 1 MHz. With the multi-cavity cascaded coupled vertical-cavity surface-emitting laser in the present disclosure, the optical field is effectively coupled from the active cavity into multiple cascaded passive cavities, and partial light is extracted and stored in a “photon reservoir” composed of passive cavities through an intermediate reflector immediately following the active region.

Within the passive cavities, the photon undergoes multiple cycles before being emitted, significantly extending the photon lifetime. The method enables a substantially longer photon lifetime compared to conventional extended-cavity and three-reflector VCSEL designs, thereby significantly compressing the linewidth of the laser, effectively extending the photon lifetime to reduce the linewidth, and showing clear advantages.

The method for manufacturing a multi-cavity cascaded coupled vertical-cavity surface-emitting laser according to the present disclosure is convenient and facilitates widespread popularization and application. The manufactured vertical-cavity surface-emitting laser shows excellent performance with a relatively long cavity length.

### BRIEF DESCRIPTION OF THE DRAWINGS

FIG. 1 is a schematic structural diagram of a coupled vertical-cavity surface-emitting laser according to an embodiment of the present disclosure;

FIG. 2 is a schematic structural diagram of a coupled vertical-cavity surface-emitting laser according to another embodiment of the present disclosure;

FIG. 3 is a schematic structural diagram of a three-cavity cascaded coupled vertical-cavity surface-emitting laser 1 according to Embodiment 1 of the specification;

FIG. 4 is a graph showing variations of an electric field intensity and a refractive index distribution with a distance for a three-cavity cascaded coupled vertical-cavity surface-emitting laser 1 according to Embodiment 1 of the specification;

FIG. 5 is a graph showing a variation of a cold-cavity linewidth with an electric field intensity ratio for a three-cavity cascaded coupled vertical-cavity surface-emitting laser 1 according to Embodiment 1 of the specification, where AC represents an electric field intensity in an active cavity and PC1 represents an electric field intensity in a first passive cavity;

FIG. 6 is a graph showing a variation of a cold-cavity linewidth with an electric field intensity ratio for a three-cavity cascaded coupled vertical-cavity surface-emitting laser 1 according to Embodiment 1 of the specification, where PC1 represents an electric field intensity in a first passive cavity and PC2 represents an electric field intensity in a second passive cavity;

FIG. 7 is a graph showing variation of a spectral linewidth with an inverse of output power for two-cavity, three-cavity, four-cavity, and five-cavity cascaded coupled vertical-cavity surface-emitting lasers according to Embodiment 6 of the specification, where 2C represents a two-cavity cascaded vertical-cavity surface-emitting laser (VCSEL), 3C represents a three-cavity cascaded VCSEL, 4C represents a four-cavity cascaded VCSEL, and 5C represents a five-cavity cascaded VCSEL;

FIG. 8 is a phase noise graph of a three-cavity cascaded coupled vertical-cavity surface-emitting laser 1 according to Embodiment 1 of the specification;

FIG. 9 is an L-I graph of a three-cavity cascaded coupled vertical-cavity surface-emitting laser 1 according to Embodiment 1 of the specification;

FIG. 10 is a graph showing a variation of a light intensity with a wavelength and a temperature for a three-cavity cascaded coupled vertical-cavity surface-emitting laser 1 according to Embodiment 1 of the specification;

FIG. 11 shows a structural diagram, and an electric field distribution graph, for a four-cavity cascaded coupled vertical-cavity surface-emitting laser 2 according to Embodiment 4 of the specification; and

FIG. 12 shows a structural diagram, and an electric field distribution graph, for a five-cavity cascaded coupled vertical-cavity surface-emitting laser 3 according to Embodiment 5 of the specification.

Reference numerals:

| | | |
|---|---|---|
| 1: First electrode, | 2: Top reflector, | 3: Oxidation layer, |
| 4: Active region, | 5: Assembly of intermediate | |
| | reflector and passive cavity, | |
| 51: Intermediate reflector, | 52: Passive cavity, | 6: Second electrode, |
| 7: Bottom reflector, | 8: Substrate, | 151: First intermediate reflector, |
| 152: First passive cavity, | 251: Second intermediate reflector, | |
| 252: Second passive cavity, | 351: Third intermediate reflector, | |
| 352: Third passive cavity, | 451: Fourth intermediate reflector, | |
| 452: Fourth passive cavity. | | |

In order to make the embodiments of the present disclosure clearer, the embodiments of the present disclosure are further described clearly and thoroughly below. It is apparent that the described embodiments are only some, rather than all embodiments of the present disclosure.

Therefore, the following detailed description of the embodiments of the present disclosure is not intended to limit the scope of the claims of the present disclosure, but merely represents selected embodiments of the present disclosure.

### DETAILED DESCRIPTION

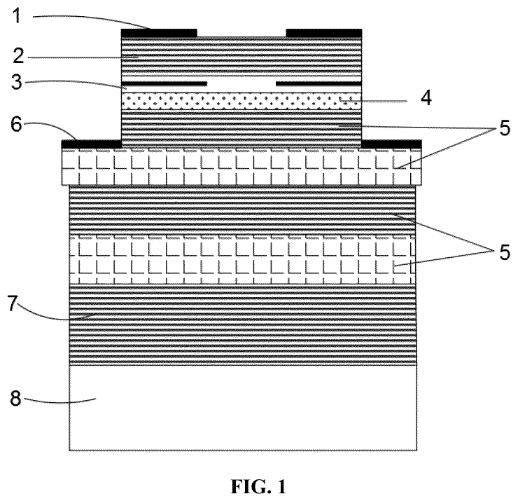

In one embodiment, a multi-cavity cascaded coupled vertical-cavity surface-emitting laser is provided according to the present disclosure. Referring to FIG. 1, the laser includes, from top to bottom, a top reflector 2, an oxidation layer 3, an active region 4, a predetermined number assemblies 5 of intermediate reflector and passive cavity, a bottom reflector 7, and a substrate 8. A first electrode 1 is arranged on a side of the top reflector 2 away from the oxidation layer 3, and a second electrode 6 is arranged at two ends of a side of an assembly 5 of intermediate reflector and passive cavity closest to the top reflector 2.

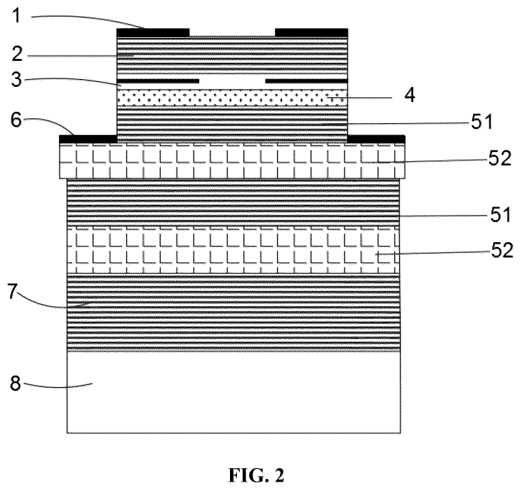

In some embodiments of the present disclosure, referring to FIG. 1 and FIG. 2, each of the assemblies 5 of intermediate reflector and passive cavity includes an intermediate reflector 51 and a passive cavity 52 located on a side of the intermediate reflector 51 away from the active region. That is, each assembly includes an intermediate reflector 51 and a passive cavity 52.

It can be understood that the multi-cavity cascaded coupled vertical-cavity surface-emitting laser according to the present disclosure addresses the issue that the requirements on a light source for a precision timing atomic clock cannot be satisfied due to a limited effective cavity length and a relatively large lasing spectral linewidth. Without an external cavity, the multi-cavity cascaded coupling linewidth compression method achieves a laser spectral linewidth below 1 MHz. An optical field is effectively coupled from an active cavity into multiple cascaded passive cavities, and partial light is extracted and stored in a “photon reservoir” composed of passive cavities through an intermediate reflector immediately following the active region. Within the passive cavities, a photon undergoes multiple cycles before being emitted, significantly extending a photon lifetime. The method enables a substantially longer photon lifetime compared to conventional extended-cavity and three-reflector vertical-cavity surface-emitting laser (VCSEL) designs, thereby significantly compressing the linewidth of the laser, and effectively extending the photon lifetime to reduce the linewidth.

Further, a method for reducing a cold-cavity linewidth with the field-modulated multi-cavity cascaded VCSEL in the present disclosure is proposed based on an equation: Δv_{c}=1/(2πτ_{c}), where Δv_{c} represents the cold-cavity linewidth and τ_{c} represents a photon lifetime within a cavity. The equation demonstrates an inverse relationship between the cold-cavity linewidth and the photon lifetime. By increasing the photon lifetime within the cavity, the cold-cavity linewidth is reduced, to reduce the spectral linewidth of the laser. Thus, by arranging multiple assemblies of intermediate reflector and passive cavity, the photon lifetime is effectively improved, thereby significantly reducing the spectral linewidth and optimizing the performance of the laser.

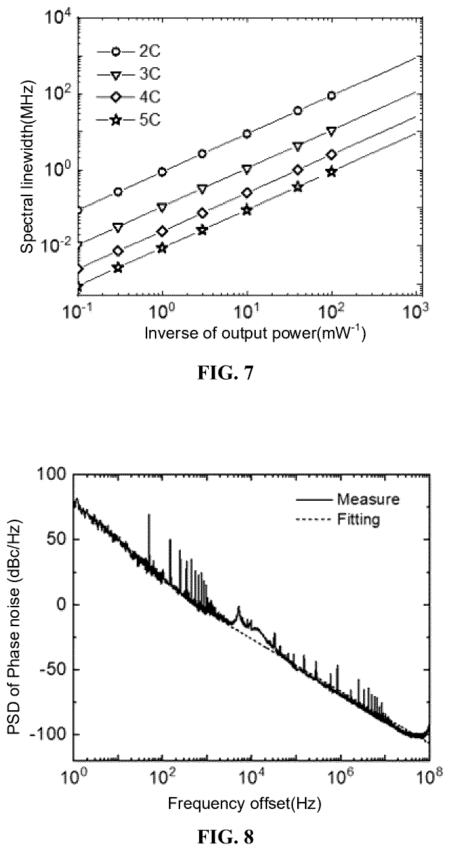

By means of theoretical analysis and calculations and comparing them with simulation results, it is derived that: for a conventional VCSEL, a cold-cavity linewidth of a resonator cavity is generally greater than 0.2 nm; and for a VCSEL with an output power less than 1 mW, an output spectral linewidth thereof exceeds 1 GHz. For a multi-cavity cascaded VCSEL, due to a photon undergoing repeated oscillation and frequency selection in multiple cavities, a cold-cavity linewidth of a resonator cavity thereof may reach below 0.01 nm. As shown in FIG. 7, at a same output power of 1 mW, the spectral linewidths of two-cavity cascaded, three-cavity cascaded, four-cavity cascaded, and five-cavity cascaded VCSELs are 0.9 MHz, 0.1 MHz, 0.02 MHz, and 0.01 MHz, respectively, which are more than two orders of magnitude less than the linewidth of the conventional VCSEL.

In some embodiments of the present disclosure, the predetermined number of the assemblies of intermediate reflector and passive cavity is 2 to 6. In some embodiments of the present disclosure, the predetermined number of the assemblies of intermediate reflector and passive cavity is 2 to 15.

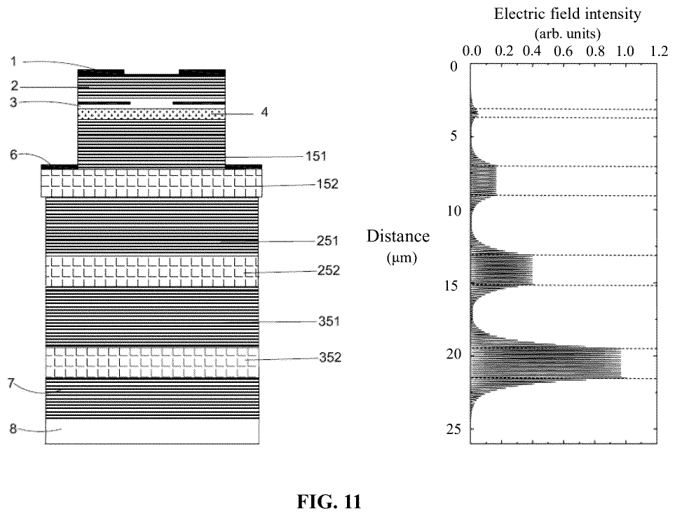

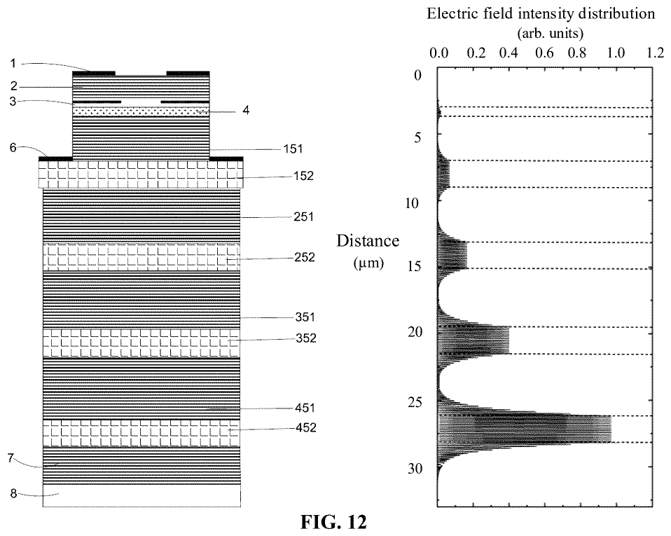

A laser with two assemblies of intermediate reflector and passive cavity may be referred to as a three-cavity cascaded coupled vertical-cavity surface-emitting laser (referring to FIG. 1 and FIG. 2 of the present disclosure); a laser with three assemblies of intermediate reflector and passive cavity may be referred to as a four-cavity cascaded coupled vertical-cavity surface-emitting laser (referring to FIG. 11 of the present disclosure); and a laser with four assemblies of intermediate reflector and passive cavity may be referred to as a five-cavity cascaded coupled vertical-cavity surface-emitting laser (referring to FIG. 12 of the present disclosure).

In some embodiments of the present disclosure, the top reflector includes 21 to 25 pairs of p-type doped Al_{0.92}Ga_{0.08}As/Al_{0.16}Ga_{0.84}As, with a doping concentration of 2×10¹⁸ to 3×10¹⁸ cm⁻³. Each of the pairs includes a layer of Al_{0.92}Ga_{0.08}As and a layer of Al_{0.16}Ga_{0.84}As, which are p-type doped.

In some embodiments of the present disclosure, the active region includes three repeating units. Each of the three repeating units includes a 6 nm In_{0.135}Ga_{0.865}As quantum well and an 8 nm Al_{0.25}Ga_{0.75}As barrier.

In some embodiments of the present disclosure, the oxidation layer is arranged between a spacer layer and a first p-DBR (p-type Distributed Bragg Reflector, or p-type doping Distributed Bragg Reflector), which is a top DBR formed by a layer of Al_{0.92}Ga_{0.08}As and a layer of Al_{0.16}Ga_{0.84}As. An oxidation aperture of the oxidation layer has a diameter of 3 μm and the oxidation layer is a 30 nm thick layer made of p-type Al_{0.98}Ga_{0.02}As with a doping concentration of 2×10¹⁸ cm⁻³, which is oxidized at a lateral side to produce Al₂O₃, forming an oxidation confinement layer with an excellent insulation property. The oxidation aperture herein refers to a part in the oxidation layer, which is not oxidized and is made of Al_{0.92}Ga_{0.08}As. In addition to limiting an emission aperture size, the oxidation confinement layer may effectively suppress electron leakage, enabling the multi-cavity cascaded coupled vertical-cavity surface-emitting laser to achieve a low-threshold single-mode laser output, thereby further optimizing device performance.

In some embodiments of the present disclosure, under a high-temperature steam condition, a surface of the Al_{0.98}Ga_{0.02}As material forms a layer of aluminum oxide. After the multi-cavity cascaded coupled VCSEL is processed into a cylindrical platform structure using an etching technique, a lateral side of the cylindrical platform structure is oxidized into insulating aluminum oxide, and an unoxidized portion at the center retains conductivity. This design ensures that current can only flow through the central conductive region, thus forming a current confinement layer, also referred to as the oxidation layer. An opening of the structure is referred to as the oxidation aperture, which also serves as an emission region of the laser. A refractive index of AlGaAs at the center of the oxidation aperture is different from a refractive index of aluminum oxide outside the oxidation aperture, and a cylindrical waveguide with a refractive index difference Δn_{eff} between a core and a cladding is formed in a radial direction of VCSEL, thereby achieving lateral optical confinement in an oxide-confined VCSEL. In the present disclosure, an optical field intensity in the passive cavity is higher than an optical field intensity in the active cavity, reducing the effective refractive index difference inside and outside the VCSEL emission aperture, thereby suppressing the generation of a higher-order mode. A higher-order mode beam has a larger divergence angle, and after suppressing the higher-order mode beam, a remaining lower-order mode beam may achieve a smaller divergence angle. An effective refractive index of the core N_{core} and an effective refractive index of the cladding N_{clad} are calculated as follows:

$${N}_{c l a d} = \frac{\int {n}_{clad} * {E}_{Z} * {d}_{z}}{\int {E}_{Z} * {d}_{z}}$$

$${N}_{c o r e} = \frac{\int {n}_{c o r e} * {E}_{Z} * {d}_{z}}{\int {E}_{Z} * {d}_{z}}$$

The effective refractive index difference inside and outside the VCSEL emission aperture is determined by the following equation:

$$Δ {n}_{eff} = {N}_{c o r e} - {N}_{c l a d} ,$$

where n_{core} and n_{clad} represent the refractive indices of the core and cladding materials, respectively, and E_{Z} represents a standing wave distribution of an electric field along a Z-direction. A smaller effective refractive index difference may reduce the number of modes, resulting in a purer spectrum.

In some embodiments of the present disclosure, each intermediate reflector includes, from bottom to top, a first n-type doped layer, a second n-type doped layer, and a third n-type doped layer. The first n-type doped layer includes 11 to 12.5 pairs of Al_{0.92}Ga_{0.08}As/Al_{0.16}Ga_{0.84}As, with a doping concentration of 1×10¹⁸ to 1.5×10¹⁸ cm⁻³, each of the layers including a layer of Al_{0.92}Ga_{0.08}As and a layer of Al_{0.16}Ga_{0.84}As. The second n-type doped layer includes an Al_{0.16}Ga_{0.84}As layer with a predetermined optical thickness, with a doping concentration of 2×10¹⁸ cm⁻³. The third n-type doped layer includes 7 to 9.5 pairs of Al_{0.92}Ga_{0.08}As/Al_{0.16}Ga_{0.84}As, with a doping concentration of 1.5×10¹⁸ to 2×10¹⁸ cm⁻³, each of the layers including a layer of Al_{0.92}Ga_{0.08}As and a layer of Al_{0.16}Ga_{0.84}As.

In some embodiments of the present disclosure, the predetermined optical thickness is λ to λ2. It should be noted that the optical thickness must be an integer times λ/2. In one embodiment, the predetermined optical thickness is 4%.

It should be noted that although the intermediate reflector described above is n-type doped, the intermediate reflector may alternatively be p-type doped and is arranged between the oxidation layer and the top reflector. This inverted design has a significant disadvantage compared to the present disclosure, which arises from a low migration efficiency of a p-type carrier that must travel a long lateral distance in the intermediate DBR (or the intermediate reflector). The low migration efficiency leads to increased overall resistance of the coupled-cavity VCSEL, resulting in lower efficiency.

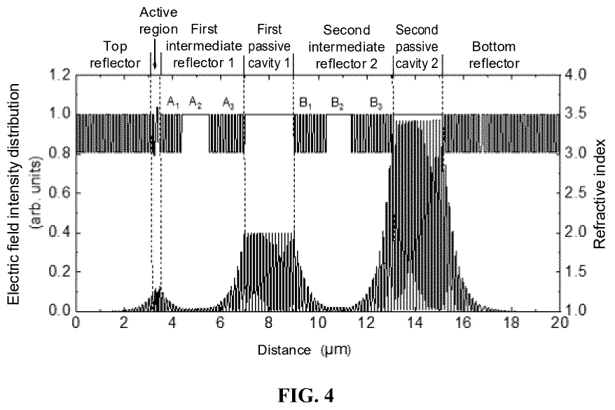

In some embodiments of the present disclosure, a dip exists in a reflection spectrum of the intermediate reflector. It should be understood that a defect is introduced in a DBR to form the intermediate reflector according to the present disclosure. Specifically, the defect is as follows. In a case where two DBRs adjacent to a middle section or layer (for example, A2 in the first intermediate reflector or B2 in the second intermediate as shown in FIG. 4) of the intermediate reflector have a same refractive index, a dip appears in the reflection spectrum of the intermediate reflector. In a case where the two DBRs adjacent to the middle section of the intermediate reflector have different refractive indices, no dip appears in the reflection spectrum of the intermediate reflector. This design is distinctly different from the VCSEL with multiple extended cavities, as it is not required that a dip appears in a reflection spectrum of an intermediate reflector for the VCSEL with multiple extended cavities.

In some embodiments of the present disclosure, the top reflector has a reflectivity of 99.3% to 99.7%, the intermediate reflector has a reflectivity of 15% to 45%, and the bottom reflector has a reflectivity of 99.9%. It should be understood that, unlike a conventional design, the optical field intensity in the passive cavity of the multi-reflector coupled-cavity VCSEL is higher than the optical field intensity in the active region. Since reflectivities of various reflector groups differ, the photon circulates in the passive cavity between the bottom reflector and the intermediate reflector, thereby increasing the photon lifetime within the cavity. Thus, by regulating the reflectivities of the various reflector groups, the photon is effectively regulated to circulate in the passive cavity, thereby increasing the photon lifetime within the passive cavity from another dimension, further improving the photon lifetime, reducing the spectral linewidth, and enhancing the performance of the laser.

In some embodiments of the present disclosure, the bottom reflector includes 36 pairs of n-type doped Al_{0.92}Ga_{0.08}As/Al_{0.16}Ga_{0.84}As, with a doping concentration of 1.5×10¹⁸ cm⁻³~2×10¹⁸ cm⁻³, each of the pairs including a layer of Al_{0.92}Ga_{0.08}As and a layer of Al_{0.16}Ga_{0.84}As, which are n-type doped.

It should be noted that the bottom reflector includes multiple alternating high-refractive-index and low-refractive-index refracting layers, which may have any appropriate combination of composition and thickness. A combination of the high-refractive-index and low-refractive-index layers is preferably selected to minimize the total number of the multiple alternating high-refractive-index and low-refractive-index refracting layers. Generally, a reflectivity of a bottom DBR is a function of the number of periods, where the larger the number of periods, the larger the reflectivity. A reflectivity of approximately 99.9% or higher is preferred, and therefore the number of periods is typically greater than 30, depending on the composition of the layers adopted.

In some embodiments of the present disclosure, the passive cavity may have any suitable composition and thickness, although a composition and a thickness that minimize optical loss and scattering within the passive cavity may be preferred.

Like the bottom reflector, the composition of the passive cavity is preferably selected to minimize a difference between a lattice constant of the passive cavity and a lattice constant of the remaining components in the multi-cavity cascaded VCSEL.

The thickness of the passive cavity is equal to an integer times half an operating wavelength in the passive cavity. In one embodiment, the thickness is at least 8 times the operating wavelength in the passive cavity.

In some embodiments of the present disclosure, the substrate may be any suitable substrate, including various semiconductor wafers such as GaAs or other III-V material wafers. The substrate is preferably a semiconductor substrate that is substantially lattice-matched with materials of the remaining components of the multi-cavity cascaded VCSEL.

In some embodiments of the present disclosure, the first electrode and/or the second electrode is made of any one of gold, copper, graphite, silver, or tin.

In one embodiment, a method for manufacturing a multi-cavity cascaded coupled vertical-cavity surface-emitting laser is further provided according to the present disclosure. Referring to FIG. 1, the method includes:
S1, providing a substrate 8, and sequentially providing, on the substrate 8, a bottom reflector 7, a predetermined number of assemblies 5 of intermediate reflector and passive cavity, an active region 4, an oxidation layer 3, and a top reflector 2, to obtain a first preform; and
S2, arranging a first electrode 1 on the top reflector of the first preform, and arranging a second electrode 6 on a side of a first assembly 5 of intermediate reflector and passive cavity closest to the top reflector 2 of the first preform, to complete manufacture of the laser.

It should be noted that during the practical process, the bottom reflector 7, predetermined number of assemblies 5 of intermediate reflector and passive cavity, active region 4, oxidation layer 3, and top reflector 2 may be provided on the substrate 8 through an epitaxial growth process. In practice, buffer layers exist between the involved layers including the bottom reflector, the intermediate reflectors and passive cavities, the active region, the oxidation layer, and the top reflector. Parameters are adjusted according to practical manufacture requirements to grow each buffer layer by an epitaxial process, to meet practical needs. By using the buffer layer as a transition layer, resistances of the intermediate DBR and the top DBR are reduced. In this way, when a driving current passes through the intermediate DBR and the top DBR, the overall efficiency of the multi-cavity cascaded VCSEL is improved.

In some embodiments of the present disclosure, the manufacture method may use a metal-organic chemical vapor deposition (MOCVD) or a molecular beam epitaxy (MBE) for epitaxial growth of the layers.

In the manufacture method of the present disclosure, the MOCVD is used for epitaxial growth of the layers, preferably. In some embodiments, the above manufacture method may further be applied to lasers of other types, such as edge-emitting semiconductor lasers or non-semiconductor lasers.

Applications of the multi-cavity cascaded coupled vertical-cavity surface-emitting laser, as described above or manufactured by the aforementioned method, are further provided in the present disclosure.

It should be understood that the manufacture method according to the present disclosure achieves a laser with an output spectral linewidth below 1 MHz without relying on external cavity multi-cavity cascade coupling linewidth compression technology. The laser shows extremely excellent performance and therefore has a broader application prospect. In the design, all cavity structures resonate at an 894.6 nm wavelength corresponding to cesium atomic transition. The design method may also be applied to other wavelengths required for precision measurements or coherent optical communications, such as 852 nm and 795 nm. The multi-cavity cascade coupling structure may also be used for linewidth compression in an edge-emitting laser. Therefore, the manufacture method in the present disclosure and the multi-cavity cascaded coupled vertical-cavity surface-emitting laser obtained by the manufacture method may be applied to special fields such as atomic clocks, demonstrating significant progress and superiority.

### Embodiment 1

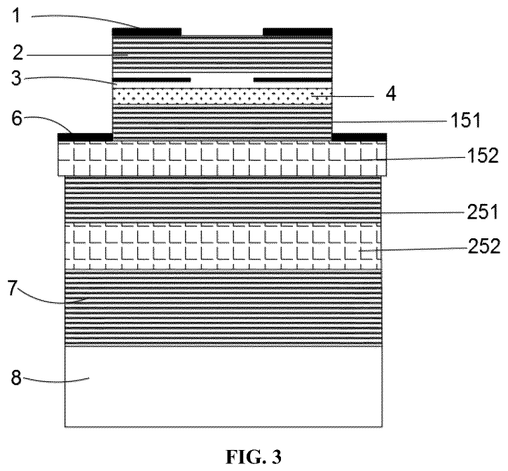

A three-cavity cascaded coupled vertical-cavity surface-emitting laser 1 is provided in this embodiment. Referring to FIG. 3 for a schematic structural diagram of the three-cavity cascaded VCSEL, the laser includes, from top to bottom, a top reflector 2, an oxidation layer 3, an active region 4, a first intermediate reflector 151, a first passive cavity 152, a second intermediate reflector 251, a second passive cavity 252, a bottom reflector 7, and a GaAs substrate 8. A first electrode 1 is arranged on a side of the top reflector 2 away from the oxidation layer 3, and a second electrode 6 is arranged at two ends of a side of the first passive cavity 152 closer to the top reflector 2.

Referring to FIG. 3, the multi-cavity cascaded coupled vertical-cavity surface-emitting laser 1 has a total of four reflectors (the top reflector 2, the first intermediate reflector 151, the second intermediate reflector 251, and the bottom reflector 7) and three cavities. An optical thickness of the whole three-cavity cascaded coupled VCSEL should be an integer times λ/2. Compared with the conventional VCSEL, two intermediate reflectors and two passive cavities are introduced.

The top reflector includes 23 pairs of p-type doped Al_{0.92}Ga_{0.08}As/Al_{0.16}Ga_{0.84}As, with a doping concentration of 2×10¹⁸ cm⁻³, each of the pairs including a layer of Al_{0.92}Ga_{0.08}As and a layer of Al_{0.16}Ga_{0.84}As, which are p-type doped. The active region includes three repeating units, for example, a first repeating unit, a second repeating unit and a third repeating unit. each of the three repeating units includes a 6 nm In_{0.135}Ga_{0.865}As quantum well and an 8 nm Al_{0.25}Ga_{0.75}As barrier. For example, the first repeating unit includes a first quantum well and a first barrier, the second repeating unit includes a second quantum well and a second barrier, and the third repeating unit includes a third quantum well and a third barrier. In embodiments, the first quantum well, the first barrier, the second quantum well, the second barrier, the third quantum well and the third barrier are arranged in the order as listed. That is, the first quantum well and the second quantum well are spaced by the first barrier, and the second quantum well and the third quantum well are spaced by the second barrier. An oxidation layer is arranged between a spacer layer and a first pair of p-DBRs. An oxidation aperture of the oxidation layer has a diameter of 3 μm and the oxidation layer is a 30 nm thick layer made of p-type Al_{0.98}Ga_{0.02}As with a doping concentration of 2×10¹⁸ cm⁻³, which is oxidized at a lateral side to produce Al₂O₃, forming an oxidation confinement layer with an excellent insulation property. The two passive cavities (the first passive cavity and the second passive cavity) are made of Al_{0.16}Ga_{0.84}As with an optical thickness of approximately 8λ (the thickness must be an integer times λ/2), which is n-type doped with a concentration of 1.5×10¹⁸ cm⁻³. The bottom reflector includes 36 pairs of n-type doped Al_{0.92}Ga_{0.08}As/Al_{0.16}Ga_{0.84}As, with a doping concentration of 2×10¹⁸ cm⁻³, each of the pairs including a layer of Al_{0.92}Ga_{0.08}As and a layer of Al_{0.16}Ga_{0.84}As, which are n-type doped. The design of the intermediate reflectors is the most challenging aspect for the multi-cavity cascaded coupled VCSEL design and is a key feature distinguishing the multi-cavity cascaded VCSEL from a VCSEL based on multiple extended cavities.

First, a composition design of the intermediate reflector of the multi-cavity cascaded VCSEL in the embodiment is as follows. Each of the intermediate reflectors includes three parts, all n-type doped. The first intermediate reflector includes, from bottom to top, A₁, A₂, and A₃. A₁ is close to the active region and includes 11 pairs of Al_{0.92}Ga_{0.08}As/Al_{0.16}Ga_{0.84}As with a doping concentration of 1×10¹⁸ cm⁻³, each of the pairs including a layer of Al_{0.92}Ga_{0.08}As and a layer of Al_{0.16}Ga_{0.84}As; A₂ is an Al_{0.16}Ga_{0.84}As layer with an optical thickness of approximately 4λ (the thickness must be an integer times λ/2) and a doping concentration of 2×10¹⁸ cm⁻³; and A₃ is close to the first passive cavity and includes of 7 pairs of Al_{0.92}Ga_{0.08}As/Al_{0.16}Ga_{0.84}As with a doping concentration of 2×10¹⁸ cm⁻³, each of the pairs including a layer of Al_{0.92}Ga_{0.08}As and a layer of Al_{0.16}Ga_{0.84}As.

The second intermediate reflector includes, from bottom to top, B₁, B₂, and B₃. B₁ includes 12.5 pairs of Al_{0.92}Ga_{0.08}As/Al_{0.16}Ga_{0.84}As, with a doping concentration of 1.5×10¹⁸ cm⁻³, each of the pairs including a layer of Al_{0.92}Ga_{0.08}As and a layer of Al_{0.16}Ga_{0.84}As; B₂ is an Al_{0.16}Ga_{0.84}As layer with an optical thickness of approximately 42 (the thickness must be an integer times 2/2) and a doping concentration of 1.5×10¹⁸ cm⁻³; and B₃ includes of 9.5 pairs of Al_{0.92}Ga_{0.08}As/Al_{0.16}Ga_{0.84}As with a doping concentration of 1.5×10¹⁸ cm⁻³, each of the pairs including a layer of Al_{0.92}Ga_{0.08}As and a layer of Al_{0.16}Ga_{0.84}As. 0.5 pair may include one of a layer of Al_{0.92}Ga_{0.08}As and a layer of Al_{0.16}Ga_{0.84}As.

Although the intermediate reflectors described above are n-type doped, the intermediate reflectors may alternatively be p-type doped and arranged between the oxidation layer and the top reflector. This inverted design has a significant disadvantage compared to the present disclosure, which arises from a low migration efficiency of a p-type carrier that must travel a long lateral distance in the intermediate DBR. The low migration efficiency leads to increased overall resistance of the coupled-cavity VCSEL, resulting in lower efficiency

Second, a structural design of the intermediate reflector of the multi-cavity cascaded VCSEL in the embodiment is as follows. The multi-reflector structure requires that the intermediate reflector has certain transmissivity, manifested as a dip in the reflection spectrum.

Thus, a defect is introduced in a DBR to form the intermediate reflector according to the present disclosure. Specifically, the defect is as follows. In a case that two DBRs adjacent to each of A₂ and B₂ have a same refractive index, a dip appears in the reflection spectrum of the intermediate reflector. In a case that the two DBRs adjacent to each of A₂ and B₂ have different refractive indices, no dip appears in the reflection spectrum of the intermediate reflector. This design is distinctly different from the VCSEL with multiple extended cavities, as it is not required that a dip appears in a reflection spectrum of an intermediate reflector for the VCSEL with multiple extended cavities.

Finally, a reflectivity design of the intermediate reflectors of the multi-cavity cascaded VCSEL in the embodiment is as follows. Unlike a conventional design, the optical field intensity in the passive cavity of the multi-reflector coupled-cavity VCSEL is higher than the optical field intensity in the active region, because reflectivities of the four reflectors differ from each other. The bottom reflector has a reflectivity of approximately 99.9%; each intermediate reflector have a reflectivity between 15% and 45%; and the top DBR has a reflectivity between 99.3% and 99.7%, thus the photon circulates in the passive cavity between the bottom reflector and the intermediate reflectors, thereby increasing the photon lifetime within the cavity.

Referring to FIG. 3, the manufacture method includes:
S1, sequentially providing, on the GaAs substrate 8, the bottom reflector 7, the second passive cavity 252, the second intermediate reflector 251, the first passive cavity 152, the first intermediate reflector 151, the active region 4, the oxidation layer 3, and the top reflector 2, to obtain a first preform; and
S2, arranging the first electrode 1 on the top reflector 2 of the first preform, and arranging the second electrodes 6 on a side of the first assembly of intermediate reflector and passive cavity closest to the top reflector 2 of the first preform, to complete a manufacture of the three-cavity cascaded coupled vertical-cavity surface-emitting laser 1.

### Embodiment 2

### 2.1 Experimental Design

In this embodiment, the three-cavity cascaded coupled vertical-cavity surface-emitting laser 1 manufactured according to Embodiment 1 is used for dynamic analysis of variations of an electric field intensity and a refractive index distribution with a distance. The analysis results are shown in FIG. 4.

### 2.2 Analysis of Experimental Results

Referring to FIG. 4, the quantum wells are located at the antinodes of the standing wave optical field to improve the coupling efficiency between carriers and photons. The oxidation layer is designed at a first node of the standing wave optical field near the quantum wells to minimize losses. The electric field intensity decays rapidly in the relatively thick and highly reflective bottom DBR; and similarly, the electric field intensity also decays rapidly in the relatively thick and highly reflective top DBR. In the passive cavities, the electric field intensity remains essentially constant at a maximum value.

In the intermediate DBRs, A₁ is adjacent to the active region, and A₃ is adjacent to the first passive cavity. The electric field intensity decays to a constant value within the doped contact region A₂. It can be observed that the optical electric field distribution of the multi-cavity cascaded VCSEL differs from that of the conventional VCSEL. In the conventional extended-cavity VCSEL, the optical field intensity in the active region is higher than the optical field intensity in the passive region. In the multi-cavity cascaded VCSEL, the optical field intensity in the passive region is higher than the optical field intensity in the active region. This optical electric field design not only effectively narrows the linewidth but also purifies the mode. The improvement in single-mode performance is due to an additional cavity spacing, which increases the diffraction loss of a higher-order mode with a larger divergence angle. The mechanisms for linewidth reduction in the two structures are different. The extended-cavity VCSEL reduces the linewidth by increasing the effective cavity length, that is, the path length of photon circulation within the cavity, while the multi-cavity cascaded VCSEL reduces the linewidth by increasing the photon lifetime, that is, the number of photon circulation cycles within the cavity. When photons generated in the active region propagate toward the first intermediate DBR, some photons are reflected back, and the rest are transmitted into the first passive cavity. The electric field intensity in the passive cavity is higher than the optical field intensity in the active region, resulting in a higher degree of energy concentration. The total electric field energy stored in the “photon reservoir” is several times greater than the electric field energy in a conventional extended cavity with a same spatial volume. The transmitted photons then undergo additional reflection and transmission at a next intermediate DBR. As a result, the photons undergo multiple reflection and transmission cycles, circulating between the active cavity and the passive cavity. The photon lifetime is effectively extended by increasing the number of oscillation cycles within the cavity for the multi-cavity cascaded VCSEL, while the photon lifetime is extended by increasing the photon propagation distance for the extended-cavity VCSEL.

### Embodiment 3

### 3.1 Experimental Design

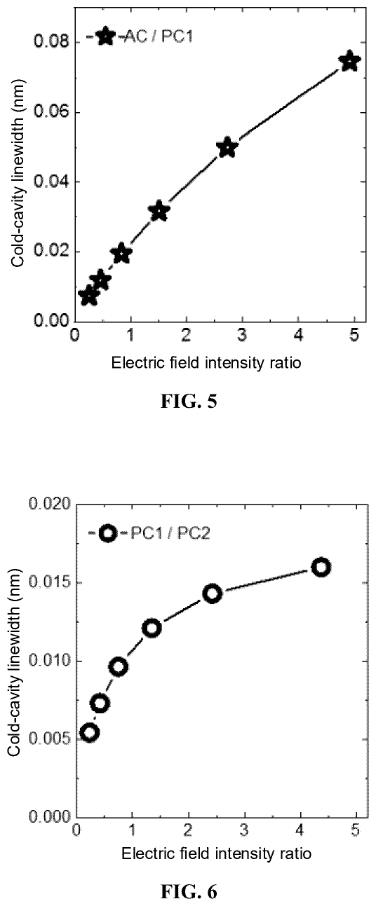

In this embodiment, the three-cavity cascaded coupled vertical-cavity surface-emitting laser 1 manufactured according to Embodiment 1 is used for analysis of a relationship between a cold-cavity linewidth and an electric field intensity ratio. The analysis results are shown in FIG. 5 and FIG. 6.

### 3.2 Analysis of Experimental Results

Referring to FIG. 5 and FIG. 6, the first intermediate reflector extracts light from the active region and stores the light in the first passive cavity. The second intermediate reflector transmits the light from the first passive cavity to the second passive cavity, forming two interconnected “photon reservoirs”. These photon reservoirs act as optical dams, storing photons and enhancing their intensity. The intermediate DBRs function as regulable valves. By regulating the number of DBR layers in A₁ and A₃, the electric field distribution can be precisely regulated. Reducing the number of DBR layers in A₁ increases the transmittance of A₁, allowing most photons from the active region to enter the first passive cavity. A portion of these photons passes through the second intermediate reflector into the second passive cavity, and oscillate repeatedly, thereby effectively increasing the photon lifetime within the entire laser cavity. According to the present disclosure, the total number of DBR layers and the total cavity length in the multi-cavity cascaded VCSEL remain unchanged throughout the process.

To simplify the following study, in the present disclosure, the electric field intensity ratio between the active cavity and the first passive cavity is expressed as r₀₁, and the electric field intensity ratio between the first passive cavity and the second passive cavity is expressed as r₁₂. When r₁₂ is fixed, the cold-cavity linewidth narrows as r₀₁ decreases. For example, in the VCSEL, when r₀₁ is ~0.3, a cold-cavity linewidth of about 7.3 μm can be achieved. When r₀₁ is increased to about 5, the cold-cavity linewidth is about 74.7 μm, which is 10 times wider than the cold-cavity linewidth of the multi-cavity cascaded VCSEL designed with a low r₀₁. Similarly, when r₀₁ is fixed, the cold-cavity linewidth of the VCSEL gradually narrows as r₁₂ decreases. It can be observed that changing the number of DBR layers in B₁ and B₃ controls the photon transfer between the first passive cavity and the second passive cavity, thereby influencing the photon lifetime, which in practice is less effective than regulating the first intermediate DBR. In addition, with reference to FIG. 5 and FIG. 6, by adjusting the number of layers of DBRs in A₁, A₃, B₁ or B₃, the distribution of the electric field can be precisely adjusted, thereby regulating the cold-cavity linewidth.

### Embodiment 4

In this embodiment, a four-cavity cascaded coupled vertical-cavity surface-emitting laser 2 is manufactured, and the structure therefore is shown in FIG. 11. The laser 2 is similar to the vertical-cavity surface-emitting laser 1 in Embodiment 1, and differs from the laser 1 in that the laser 2 has three intermediate reflectors.

The four-cavity cascaded coupled vertical-cavity surface-emitting laser 2 includes, from top to bottom, includes: a top reflector 2, a oxidation layer 3, an active region 4, a first intermediate reflector 151, a first passive cavity 152, a second intermediate reflector 251, a second passive cavity 252, a third intermediate reflector 351, a third passive cavity 352, a bottom reflector 7, and a substrate 8. A first electrode 1 is arranged on a side of the top reflector 2 away from the oxidation layer 3, and a second electrode 6 is arranged at two ends of a side of the first passive cavity 152 closer to the top reflector 2.

The manufacture method of the laser 2 is the same as the fabrication method in Embodiment 1, except that the third intermediate reflector 351 and the third passive cavity 352 are additionally provided in the intermediate layers.

### Embodiment 5

In this embodiment, a five-cavity cascaded coupled vertical-cavity surface-emitting laser 3 is manufactured, and the structure thereof is shown in FIG. 12. The laser 3 is similar to the vertical-cavity surface-emitting laser 1 in Embodiment 1, and differs from the laser 1 in that the laser 3 has four intermediate reflectors.

The five-cavity cascaded coupled vertical-cavity surface-emitting laser 3 includes, from top to bottom: a top reflector 2, a oxidation layer 3, an active region 4, a first intermediate reflector 151, a first passive cavity 152, a second intermediate reflector 251, a second passive cavity 252, a third intermediate reflector 351, a third passive cavity 352, a fourth intermediate reflector 451, a fourth passive cavity 452, a bottom reflector 7, and a substrate 8. A first electrode 1 is arranged on a side of the top reflector 2 away from the oxidation layer 3, and a second electrode 6 is arranged at two ends of a side of the first passive cavity 152 closer to the top reflector 2.

The manufacture method of the laser 3 is the same as the fabrication method in Embodiment 1, except that the third intermediate reflector 351, the third passive cavity 352, the fourth intermediate reflector 451, and the fourth passive cavity 452 are additionally provided in the intermediate layers.

### Embodiment 6

### 6.1 Experimental Design

In this embodiment, a commercially available common VCSEL, a VCSEL with an output power less than 1 mW, and the three-cavity cascaded coupled vertical-cavity surface-emitting laser 1 according to Embodiment 1 are selected for theoretical calculation analysis of an output spectral linewidth.

### 6.2 Analysis of Experimental Results

By means of theoretical analysis and calculations and comparing them with simulation results, it is derived that: for the conventional VCSEL, a cold-cavity linewidth of a resonator cavity is generally greater than 0.2 nm; for the VCSEL with an output power less than 1 mW, the output spectral linewidth thereof exceeds 1 GHz; and for the multi-cavity cascaded VCSEL, due to the photons undergoing repeated oscillation and frequency selection in multiple cavities, a cold-cavity linewidth of a resonator cavity thereof may reach below 0.01 nm.

### Embodiment 7

### 7.1 Experimental Design

In this embodiment, a commercially available two-cavity cascaded coupled vertical-cavity surface-emitting laser, the three-cavity cascaded coupled vertical-cavity surface-emitting laser 1 according to Embodiment 1, the four-cavity cascaded coupled vertical-cavity surface-emitting laser 2 according to Embodiment 4, and the five-cavity cascaded coupled vertical-cavity surface-emitting laser 3 according to Embodiment 5 are selected to measure the variations of a spectral linewidth with an inverse of an output power.

The results are shown in FIG. 7.

### 7.2 Analysis of Experimental Results

As shown in FIG. 7, at a same output power of 1 mW, the spectral linewidths of two-cavity, three-cavity, four-cavity, and five-cavity cascaded VCSELs are 0.9 MHz, 0.1 MHZ, 0.02 MHz, and 0.01 MHz, respectively, which are more than two orders of magnitude less than the linewidth of the conventional VCSEL.

### Embodiment 8

### 8.1 Experimental Design

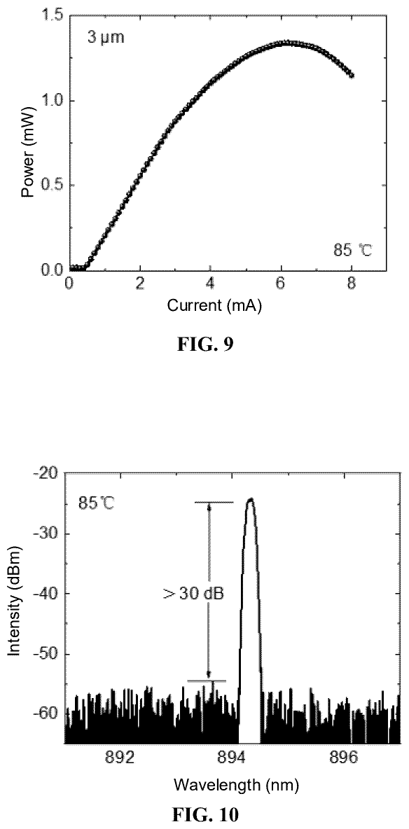

In this embodiment, the three-cavity cascaded coupled vertical-cavity surface-emitting laser 1 according to Embodiment 1 is selected to perform a phase noise measurement, as shown in FIG. 8. The three-cavity cascaded coupled vertical-cavity surface-emitting laser 1 according to Embodiment 1 is selected to perform an L-I curve measurement, as shown in FIG. 9. The three-cavity cascaded coupled vertical-cavity surface-emitting laser 1 according to Embodiment 1 is selected to measure a variation of a light intensity with a wavelength, as shown in FIG. 10.

### 8.2 Analysis of Experimental Results

Referring to FIG. 8, a Lorentzian linewidth of the three-cavity cascaded coupled vertical-cavity surface-emitting laser 1 according to Embodiment 1 is less than 1 MHz.

Referring to FIG. 9, the L-I graph of the three-cavity cascaded coupled vertical-cavity surface-emitting laser 1 according to Embodiment 1 indicates that for 3 μm VCSELs, a maximum optical output power at 85 degrees Celsius is about 1.3 mW, and a threshold current (Ith) is about 0.45 mA, meeting a low-power consumption requirement.

Referring to FIG. 10, the variation of the light intensity with the wavelength for the three-cavity cascaded coupled vertical-cavity surface-emitting laser 1 according to Embodiment 1 indicates that an emission wavelength of the three-cavity cascaded VCSEL at 85 degrees Celsius is 894.6 nm, precisely corresponding to the line wavelength D1 of cesium, with a side-mode suppression ratio (SMSR) exceeding 30 dB. As can be seen from the spectrum, the three-cavity cascaded VCSEL exhibits a significantly pure single mode at 85 degrees Celsius.

In summary, based on the manufacture and parameter measurements according to Embodiments 1 to 8, it can be derived that the coupled vertical-cavity surface-emitting lasers 1 to 3 according to the present disclosure exhibit excellent device performance, including: the spectral linewidth of the laser below 1 MHz, meeting the low-power consumption requirement, and highly pure single mode. Thus, the multi-cavity cascaded coupled vertical-cavity surface-emitting laser according to the present disclosure addresses the issue of a limited effective cavity length and a relatively large lasing spectral linewidth in conventional vertical-cavity surface-emitting lasers. Due to the superior performance, the multi-cavity cascaded coupled vertical-cavity surface-emitting laser can be applied to scenarios such as light sources for atomic clocks. Additionally, the manufacture method is convenient and facilitates widespread popularization and application, with a high superiority.

The above embodiments, which are described specifically and in detail, only represent several implementations of the present disclosure, and should not be construed as limiting the scope of the present disclosure. It should be noted that various modifications and improvements fall within the protection scope of the present disclosure. Therefore, the protection scope of the present disclosure is defined by the claims.

1. A multi-cavity cascaded coupled vertical-cavity surface-emitting laser, comprising, from top to bottom, a top reflector, an oxidation layer, an active region, a predetermined number of assemblies of intermediate reflector and passive cavity, a bottom reflector, and a substrate,
wherein a first electrode is arranged on a side of the top reflector away from the oxidation layer, and a second electrode is arranged at two ends of a side of an assembly of intermediate reflector and passive cavity closest to the top reflector.

2. The laser according to claim 1, wherein each of the assemblies of intermediate reflector and passive cavity comprises an intermediate reflector and a passive cavity located on a side of the intermediate reflector away from the active region.

3. The laser according to claim 1, wherein the predetermined number of the assemblies of intermediate reflector and passive cavity is 2 to 6.

4. The laser according to claim 1, wherein the top reflector comprises 21 to 25 pairs of p-type doped Al_{0.92}Ga_{0.08}As/Al_{0.16}Ga_{0.84}As, with a doping concentration of 2×10¹⁸ to 3×10¹⁸ cm⁻³.

5. The laser according to claim 1, wherein the active region comprises three repeating units, each of the three repeating units comprising a 6 nm In_{0.135}Ga_{0.865}As quantum well separated and 8 nm Al_{0.25}Ga_{0.75}As barrier.

6. The laser according to claim 2, wherein each intermediate reflector comprises, from bottom to top, a first n-type doped layer, a second n-type doped layer, and a third n-type doped layer,
the first n-type doped layer comprising 11 to 12.5 pairs of Al_{0.92}Ga_{0.08}As/Al_{0.16}Ga_{0.84}As, with a doping concentration of 1×10¹⁸ to 1.5×10¹⁸ cm⁻³;
the second n-type doped layer comprising an Al_{0.16}Ga_{0.84}As layer with a predetermined optical thickness, with a doping concentration of 2×10¹⁸ cm⁻³; and
the third n-type doped layer comprising 7 to 9.5 pairs of Al_{0.92}Ga_{0.08}As/Al_{0.16}Ga_{0.84}As, with a doping concentration of 1.5×10¹⁸ to 2×10¹⁸ cm⁻³.

7. The laser according to claim 6, wherein the predetermined optical thickness is Δ to 4λ.

8. The laser according to claim 2, wherein a dip exists in a reflection spectrum of the intermediate reflector.

9. The laser according to claim 2, wherein the top reflector has a reflectivity of 99.3% to 99.7%, the intermediate reflector has a reflectivity of 15% to 45%, and the bottom reflector has a reflectivity of 99.9%.

10. A method for manufacturing a multi-cavity cascaded coupled vertical-cavity surface-emitting laser according to claim 1, the method comprising:
S1, providing a substrate, and sequentially providing, on the substrate, a bottom reflector, a predetermined number of assemblies of intermediate reflector and passive cavity, an active region, an oxidation layer, and a top reflector, to obtain a first preform; and
S2, arranging a first electrode on the top reflector of the first preform, and arranging a second electrode on a side of a first assembly of intermediate reflector and passive cavity closest to the top reflector of the first preform, to complete manufacture of the laser.

11. The method according to claim 10, wherein each of the assemblies of intermediate reflector and passive cavity comprises an intermediate reflector and a passive cavity located on a side of the intermediate reflector away from the active region.

12. The method according to claim 10, wherein the predetermined number of the assemblies of intermediate reflector and passive cavity is 2 to 6.

13. The method according to claim 10, wherein the top reflector comprises 21 to 25 pairs of p-type doped Al_{0.92}Ga_{0.08}As/Al_{0.16}Ga_{0.84}As, with a doping concentration of 2×10¹⁸ to 3×10¹⁸ cm⁻³.

14. The method according to claim 10, wherein the active region comprises three repeating units, each of the three repeating units comprising a 6 nm In_{0.135}Ga_{0.865}As quantum well and an 8 nm Al_{0.25}Ga_{0.75}As barrier.

15. The method according to claim 11, wherein each intermediate reflector comprises, from bottom to top, a first n-type doped layer, a second n-type doped layer, and a third n-type doped layer,
the first n-type doped layer comprising 11 to 12.5 pairs of Al_{0.92}Ga_{0.08}As/Al_{0.16}Ga_{0.84}As, with a doping concentration of 1×10¹⁸ to 1.5×10¹⁸ cm⁻³;
the second n-type doped layer comprising an Al_{0.16}Ga_{0.84}As layer with a predetermined optical thickness, with a doping concentration of 2×10¹⁸ cm⁻³; and
the third n-type doped layer comprising 7 to 9.5 pairs of Al_{0.92}Ga_{0.08}As/Al_{0.16}Ga_{0.84}As, with a doping concentration of 1.5×10¹⁸ to 2×10¹⁸ cm⁻³.

16. The method according to claim 15, wherein the predetermined optical thickness is λ to 4λ.

17. The method according to claim 11, wherein a dip exists in a reflection spectrum of the intermediate reflector.

18. The method according to claim 11, wherein the top reflector has a reflectivity of 99.3% to 99.7%, the intermediate reflector has a reflectivity of 15% to 45%, and the bottom reflector has a reflectivity of 99.9%.
